(19) United States
(12) Patent Application Publication
(10) Pub. No.: US 2011/0205717 A1
(43) Pub. Date: Aug. 25, 2011

(54) MOBILE TERMINAL AND METHOD OF MANUFACTURING THE SAME

(75) Inventors: Hiromichi Suzuki, Tokyo (JP); Natsumi Endo, Sagamihara-shi (JP); Makoto Shibuya, Tokyo (JP)

(73) Assignee: KABUSHIKI KAISHA TOSHIBA, Tokyo (JP)

(21) Appl. No.: 12/845,960

(22) Filed: Jul. 29, 2010

(30) Foreign Application Priority Data
Feb. 24, 2010 (JP) P2010-038972

(51) Int. Cl. H05K 1/00; H05K 7/00; B29C 45/14

(52) U.S. Cl. 361/749; 361/757; 264/263

(57) ABSTRACT

According to one embodiment, a mobile terminal is provided. The mobile terminal includes: a board in which an electronic circuit is mounted; a resin frame configured to hold the board; and a sheet metal configured to maintain strength of the resin frame. The resin frame is configured to be integrally molded with the board and the sheet metal.

### CROSS REFERENCE TO RELATED APPLICATION(S)

The present disclosure relates to the subject matters contained in Japanese Patent Application No. 2010-038972 filed on Feb. 24, 2010, which are incorporated herein by reference in its entirety.

### FIELD

Embodiments, described herein relate generally to a mobile terminal and a method of manufacturing the mobile terminal in which a board and a sheet metal are to be built, while the board and the sheet metal are integrally molded with a resin.

### BACKGROUND

In mobile terminals such cellular phones, there is such a trend that users want to purchase slim type terminals having good designs, and simple low-cost terminals equipped with delimited functions. As a result, small and thin type components and low profile component technologies are required for manufacturers of mobile terminals. In particular, while antennas require to occupy a certain space in order to achieve desirable performance thereof, if volumes required as antenna solely-occupied bodies are secured, then the mobile terminals are made thicker.

On the other hand, in order to manufacture mobile terminals in low costs, another requirement is made, namely, process steps must be reduced, for instance, a large number of commonly available components are utilized in a plurality of mobile terminals. In this case, as an antenna mounting method, for example, a component in which an antenna is formed on a strength maintaining member (plate for key sheet etc.) is molded with a housing (resin) in an integral manner. As a result, a total number of antenna components is reduced, and a total number of antenna mounting steps is decreased.

JP-A-2009-206795 discloses a related-art electronic device capable of realizing a small body and of suppressing a deterioration of an antenna characteristic. The related-art electronic device is provided with a circuit board, an antenna board, a first power feeding pattern, a matching circuit, and a power feeding spring, while the first power feeding pattern is formed in such a manner that the first power feeding pattern is overlapped with the antenna board along a vertical direction in the circuit board. The circuit board has a first plane and a second plane. The antenna board is arranged on a side of the first plane in the circuit board, and a chip antenna is mounted on the antenna board. The first power feeding pattern is formed on the second plane so as to feed the chip antenna. The matching circuit is formed on the second plane and is electrically connected to the first power feeding pattern. The power feeding spring is arranged between the first plane and the antenna board, is electrically connected to the matching circuit, and powers the chip antenna.

However, when the mobile terminals are made by emphasizing smallness and flexibility in order to improve design characteristics of the mobile terminals, strengths of the mobile terminals can be hardly secured.

### BRIEF DESCRIPTION OF THE DRAWINGS

A general configuration that implements the various feature of the invention will be described with reference to the drawings. The drawings and the associated descriptions are provided to illustrate embodiments of the invention and not to limit the scope of the invention.

FIG. 1 is a perspective view showing a mobile terminal (cellular phone) according to an embodiment.

FIG. 2A is an exploded perspective view showing one example of a condition under which an antenna integrally-formed frame of the mobile terminal (cellular phone) is exploded, and FIG. 2B is an assembled perspective view showing one example of a condition under which the antenna integrally-formed frame is molded in an integral manner.

FIG. 3A is an enlarged perspective view showing an antenna board of the mobile terminal (cellular phone), FIG. 3B is a perspective view showing a condition under which the antenna board and sheet metal are molded with a resin frame in an integral manner, and FIG. 3C is a perspective view showing a condition under which a cable is connected to an antenna integrally-formed frame, namely, the antenna board.

FIG. 4A is an exploded perspective view showing another example of a condition under which an antenna integrally-formed frame of the mobile terminal (cellular phone) is exploded, and FIG. 4B is an assembled perspective view showing another example of a condition under which the antenna integrally-formed frame is molded in an integral manner.

FIG. 5A is an exploded perspective view showing another example of a condition under which an antenna integrally-formed frame of the mobile terminal (cellular phone) is exploded, and FIG. 5B is an assembled perspective view showing another example of a condition under which the antenna integrally-formed frame is molded in an integral manner.

FIG. 6 is an exploded perspective view showing one example in which a coaxial connector of an antenna board is contacted to sheet metal by employing, for example, a plate spring in the antenna integrally-formed frame.

FIG. 7 is an exploded perspective view showing another example in which a coaxial connector of an antenna board is contacted to sheet metal by employing, for example, a plate spring in the antenna integrally-formed frame.

FIG. 8 is a diagram schematically showing an antenna integrally-formed frame in which an antenna board is manufactured by a flexible printed board in the mobile terminal (cellular phone).

### DETAILED DESCRIPTION

In general, according to one embodiment, a mobile terminal is provided. The mobile terminal includes: a board in which an electronic circuit is mounted; a resin frame configured to hold the board; and a sheet metal configured to maintain strength of the resin frame. The resin frame is configured to be integrally molded with the board and the sheet metal.

Referring to accompanying drawings, a description is made of embodiment modes of a mobile terminal according to an embodiment. A cellular phone 1 is exemplified and described as the mobile terminal according to the embodiment.

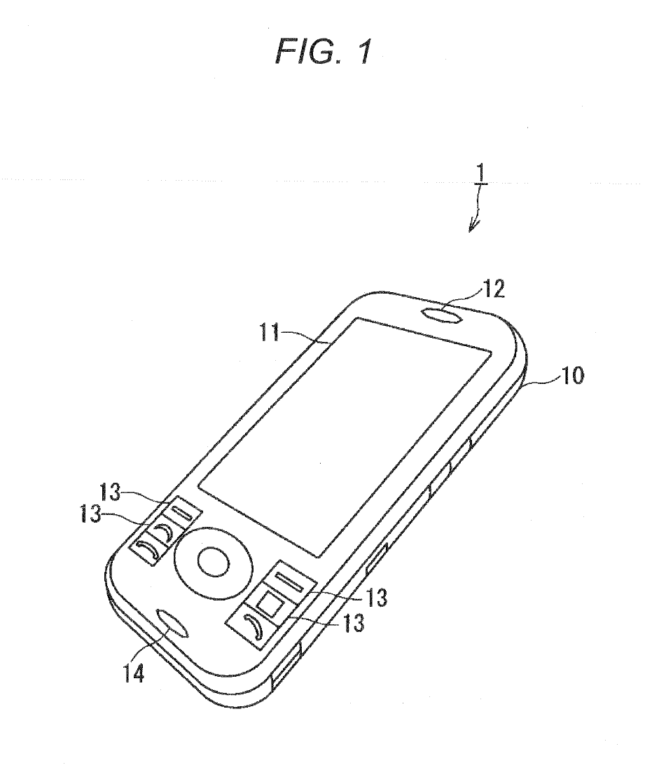

FIG. 1 is a perspective view showing the cellular phone 1. As shown in FIG. 1, the cellular phone 1 is provided with a housing 10 having a rectangular plate. The housing 10 includes a board on which various sorts of electronic circuits such as a Central Processing Unit (CPU) are mounted, a board on which an antenna is mounted, a board on which a display and a keyboard (operation keys 13 which will be described later) are mounted, an antenna integrally-formed frame 20 on which a battery pack and the like are mounted, and other components.

A display 11 for displaying data, a speaker 12 for outputting voice, operation keys 13 for inputting data by a user operation, and a microphone 14 for entering voice are provided on one plane of the housing 10. The operation keys 13 includes, for instance, cross keys for moving a cursor and a displayed screen along upper, lower, right, and left directions; a selection key for selecting an item; numeral keys for entering numerals; a telephone calling key for performing a telephone calling process, and the like.

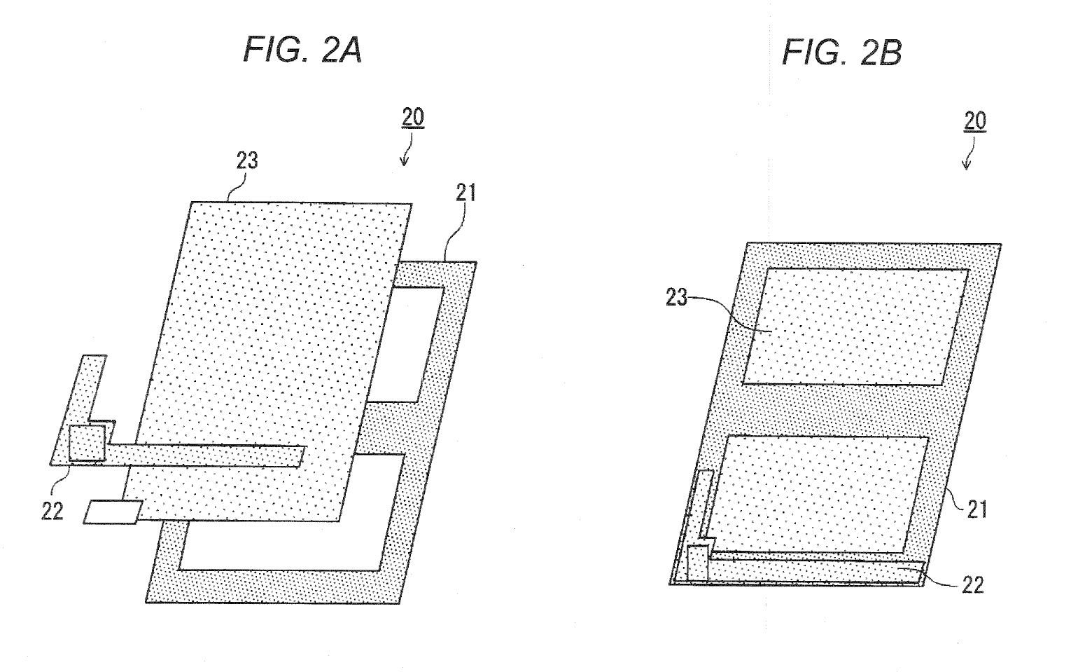

FIG. 2A is an exploded perspective view showing a condition under which the antenna integrally-formed frame 20 to be stored inside the housing 10 is exploded, and FIG. 2B is an assembled perspective view showing a condition under which the antenna integrally-formed frame 20 is molded in an integral manner. As shown in FIG. 2A, the antenna integrally-formed frame 20 is provided with a resin frame 21, an antenna board 22, and a sheet metal 23. The resin frame 21 holds respective components to be built in the cellular phone 1. The antenna board 22 is a board on which an antenna is patterned. The sheet metal 23 is a strength maintaining member, and has an electric conductive body.

The resin frame 21 is a frame for holding various sorts of boards such as the antenna board 22, the sheet metal 23, the boards for the display and the keyboard, and various sorts of components such as the battery pack, while the resin frame 21 fixes the respective boards and components at given positions thereof. As shown in FIG. 2B, the resin frame 21 is molded with the antenna board 22 and the sheet metal 23 in an integral manner such that the antenna board 22 and the sheet metal 23 are fixed at given positions. In this case, for instance, the antenna board 22 and the sheet metal 23 are fixed at the given positions in an inner portion of a metal die (not shown), a resin is caused to flow into the metal die so as to mold the components in an integral manner.

Since the resin frame 21 plays a role of storing various sorts of electronic components, as an entire shape of the resin frame 21, for example, a rectangular outer frame is required to be made. A supporting rod may be additionally provided inside the resin frame 21 in order to maintain strengths thereof with respect to external forces. The resin frame 21 may be formed into, for example, a shape having two opening portions as shown FIG. 2B. Since the resin frame 21 is formed into the shape having the two opening portions, a large number of components may be easily stored in the opening portions of the resin frame 21, and furthermore, while strengths of the resin frame 21 may be maintained, the resin frame 21 may be made in light weight. It should be noted that the shape of the resin frame 21 is not limited only to the shape having the two opening portions, but may be made in any arbitrary forms, for instance, a shape having three opening portions, a shape having four opening portions, and the like, if these alternative shapes may have opening portions and may maintain strengths.

A main antenna (not shown) of the cellular phone 1 is mounted on the antenna board 22. The antenna board 22 is formed, for example, into an L-shaped structure viewed on the front plane in order that the antenna board 22 may be fixed on a portion of the resin frame 21. The shape of the antenna board 22 is the same as a portion of the resin frame 21. Then, as shown in FIG. 2B, the antenna board 22 is molded with the resin frame 21 in an integral manner under such a condition that the antenna board 22 is mounted in line with a portion of the resin frame 21. As a result, the antenna board 22 is firmly fixed at a given position of the resin frame 21, so that positional fluctuations of the main antenna of the cellular phone 1 may be prevented.

The sheet metal 23 is a metal plate used for maintaining the strengths of the antenna integrally-formed frame 20 with respect to the external forces, while an outer shape of the sheet metal 23 is made to have the same shape as that of the resin frame 21. Then, when the sheet metal 23 is molded with the resin frame 21 in the integral manner, the sheet metal 23 covers the entire inner plane of the resin frame 21 in the integral forming process.

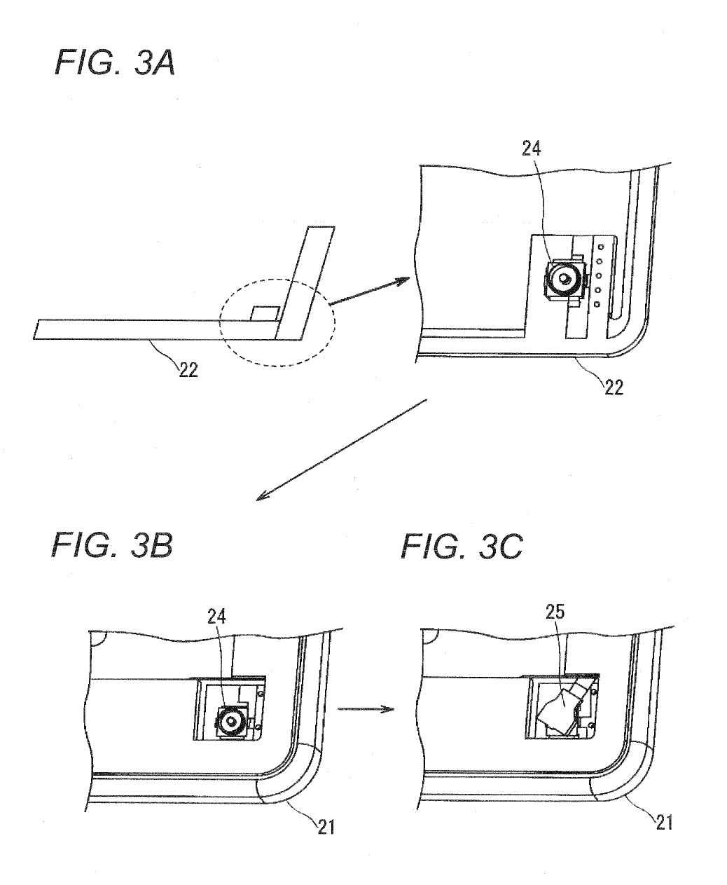

FIG. 3A is an enlarged perspective view showing the antenna board 22. FIG. 3B is a perspective view showing a condition under which the antenna board 22 and the sheet metal 23 are molded with the resin frame 21 in an integral manner. FIG. 3C is a perspective view showing a condition under which a cable is connected to the antenna board 22 of the antenna integrally-formed frame 20.

As shown in FIG. 3A, a coaxial connector 24 is mounted on a portion of the antenna board 22. Then, as shown in FIG. 3B, when the antenna board 22 and the sheet metal 23 are molded with the resin frame 21 in the integral manner, the integral molding is carried out such that the coaxial connector 24 of the antenna board 22 is exposed to an external space under such a condition that the antenna board 22 is integrally molded with the resin frame 21. Since the coaxial connector 24 is exposed to the external space in the antenna integrally-formed frame 20, as shown in FIG. 3C, the antenna board 22 can be simply powered by connecting a coaxial cable 25 from the external space to the coaxial connector 24 under exposed condition. The connecting method may be arbitrarily selected, for example, a connecting method with employment of a plate spring may be employed.

As previously described, in the mobile terminal (cellular phone 1) provided with the strength maintaining member having the electric conductive characteristic, the antenna board 22 is molded with the resin frame 21 in the integral manner by employing the resin so as to fix the antenna board 22 at the given position of the resin frame 21. As a result, a total number of components and a total number of mounting steps can be reduced and the fluctuations in the mounting positions can be decreased. Also, the strength maintaining member such as the sheet metal 23 is molded with the resin frame 21 in the integral manner so as to fix the sheet metal 23 in an outer frame of the resin frame 21. As a result, while the antenna integrally-formed frame 20 can be made slim, the strengths thereof can be improved.

Moreover, in the above-described cellular phone 1, for instance, since the coaxial connector 24 is mounted on the antenna integrally-formed frame 20, the antenna can be simply powered. That is, since various sorts of components are mounted on a board (not shown) which is integrally molded with the resin frame 21, functions which are realized in the cellular phone 1 can be increased while the total number of components and the total number of mounting steps can be reduced.

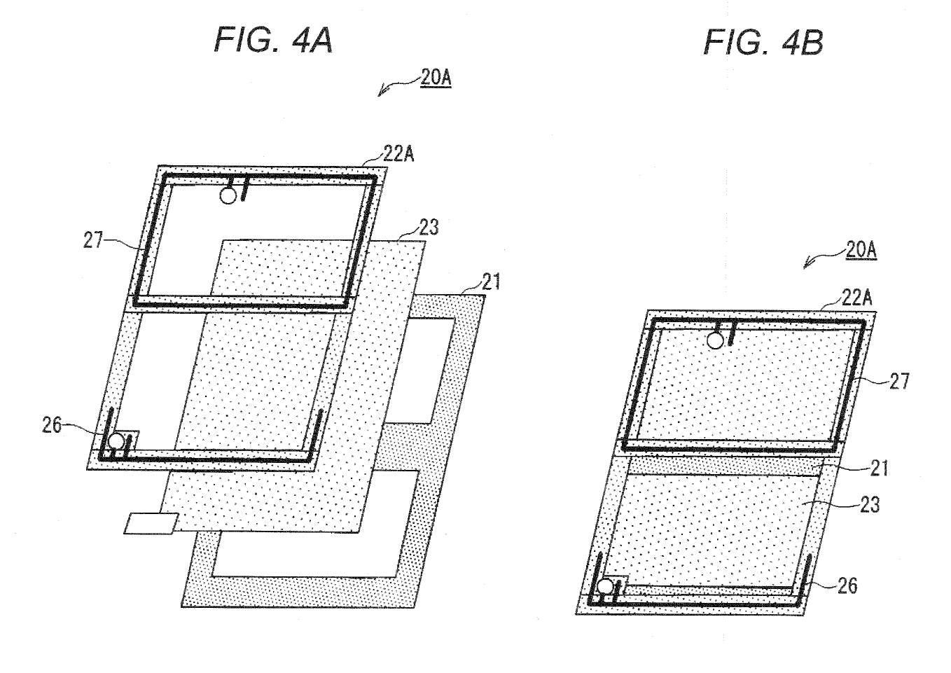

FIG. 4A is an exploded perspective view showing a condition under which an antenna integrally-formed frame 20A of the cellular phone 1 is exploded. FIG. 4B is an assembled perspective view showing a condition under which the antenna integrally-formed frame 20A of the cellular phone 1 is molded in an integral manner.

As shown in FIG. 4A, an antenna board 22A of the antenna integrally-formed frame 20A is formed in a shape having two opening portions which is the same shape as that of the resin frame 21; a main antenna 26 is patterned at a given position (for example, first position); and an antenna 27 which communicates based upon a second communication standard is patterned at another position (for instance, second position).

Then, as shown in FIG. 4B, the antenna board 22A is molded with the resin frame 21 in the integral manner such that the antenna board 22A is mounted in line with the shape of the resin frame 21, so that the main antenna 26 and the antenna 27 which communicates based upon the second communication standard are fixed at given positions respectively on the resin frame 21. As shown in FIG. 3B, the antennas 26 and 27 are integrally molded with the resin frame 21 such that the coaxial connector 24 is exposed to the external space under such a condition that the antennas 26 and 27 is molded with the resin frame 21 in the integral manner.

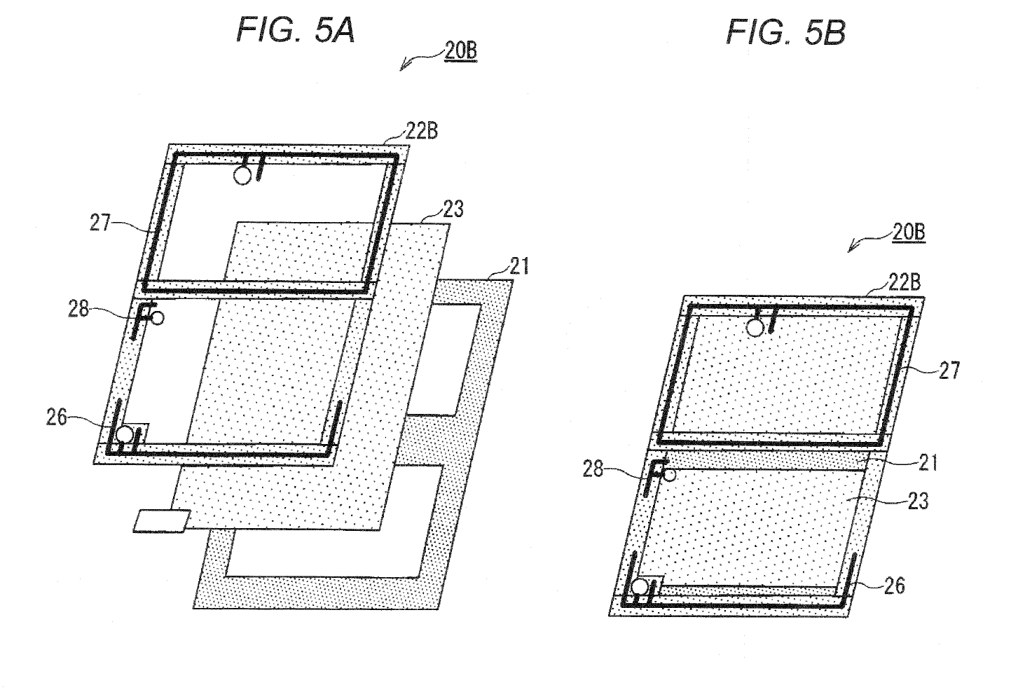

As previously explained, if the shapes of the antenna boards 22 and 22A can be made in such shapes capable of being integrally molded with the resin frame 21, then the shapes of the antenna boards 22 and 22A may be arbitrarily made. Alternatively, a plurality of antennas may be patterned on the antenna boards 22 and 22A. Although the two antennas 26 and 27 patterned on the antenna integrally-formed frame 20 have been exemplified, the embodiment is not limited only to the exemplification. That is, as shown in FIGS. 5A and 5B, more than 3 antennas may be alternatively patterned on the antenna board 22.

FIG. 5A is an exploded perspective view showing a condition under which an antenna integrally-formed frame 20B of the cellular phone 1 is exploded. FIG. 5B is an assembled perspective view showing a condition under which the antenna integrally-formed frame 20B is molded in an integral manner.

As shown in FIG. 5A, an antenna board 22B of the antenna integrally-formed frame 20B is formed in a shape having two opening portions which is the same shape as that of the resin frame 21; a main antenna 26 is patterned at a given position (for example, first position); and an antenna 27 which communicates based upon the second communication standard is patterned at another position (for instance, second position). In addition, an antenna 28 which communicates based upon a third communication standard is patterned at another position (for instance, third position).

Then, as shown in FIG. 5B, the antenna board 22B is molded with the resin frame 21 in the integral manner such that the antenna board 22B is located in line with the shape of the resin frame 21, so that the main antenna 26, the antenna 27 which communicates based upon the second communication standard, and the antenna 28 which communicates based upon the third communication standard are fixed to portions of the resin frame 21. As shown in FIG. 3B, the antennas 26, 27, 28 are integrally molded with the resin frame 21 such that the coaxial connector 24 is exposed to the external space under such a condition that the antennas 26, 27, 28 is molded with the resin frame 21 in the integral manner.

The communication standards (second communication standard, third communication standard, etc.) of the respective antennas 27, 28, and the like are arbitrarily selected from, for instance, Near Field Communication (NFC), Bluetooth (registered trademark), Wi-Fi (registered trademark), and the like.

Also, in the cellular phone 1, the plurality of antennas 26, 27, 28 are patterned on the antenna boards 22, 22A, 22B. The antenna integrally-formed frame 20, 20A, 20B manufactured by integrally molding the antenna boards 22, 22A, 22B with the resin frame 21 can be properly operated with respect to a plurality of systems. Furthermore, while the mounting fluctuations of the antenna boards 22, 22A, 22B can be suppressed, the antennas 26, 27, 28 can be mounted at the positions separated from the sheet metal 23 within a range where an adverse influence is not given to designs of the cellular phone 1. As a result, antenna performance may be improved.

While the entire portion of the resin frame 21 is formed in the shape having the two opening portions as shown in FIG. 2A, the antenna board 22 is integrally molded with the resin frame 21 under such a condition that the entire antenna board 22 is covered by the resin frame 21, and the sheet metal 23 supports the inner portion of the resin frame 21, so that rigidity of the entire antenna integrally-formed frame 20 may be increased. Moreover, since a large number of components are mounted on the antenna integrally-formed frame 20, the cellular phone 1 may be provided with a large number of functions without making the dimension of the cellular phone 1 larger.

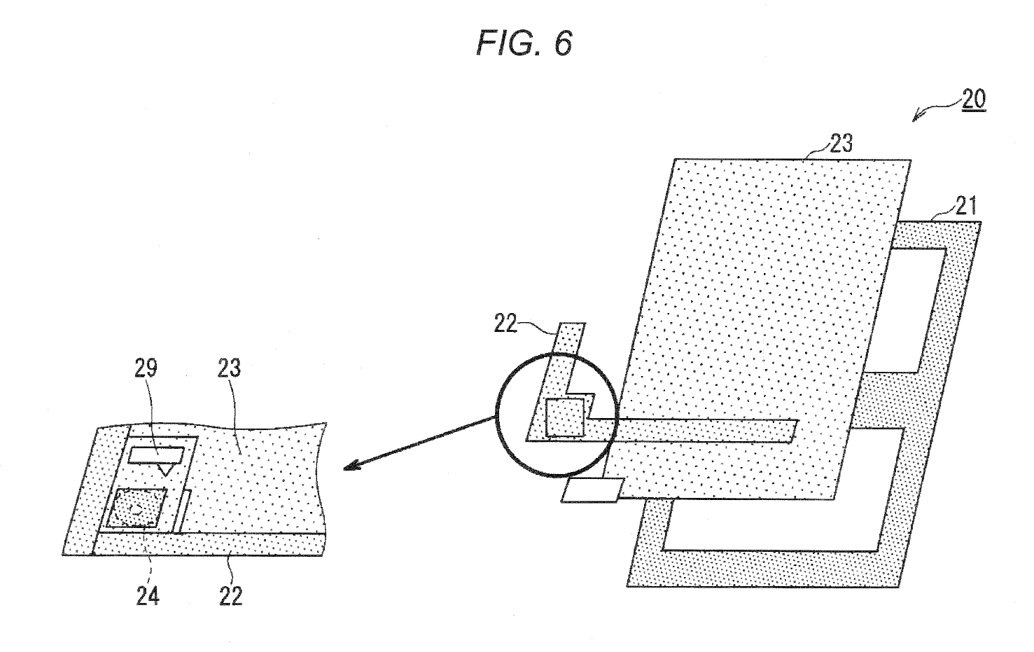

FIG. 6 is an exploded perspective view showing an example in which in the antenna integrally-formed frame 20 of the cellular phone 1, the coaxial connector 24 of the antenna board 22 is caused to be contacted to the sheet metal 23 by employing, for example, a plate spring 29. As shown in FIG. 6, the coaxial connector 24 of the antenna board 22 is connected via the plate spring 29 and mounting components to the sheet metal 23, or another board (not shown). As a result, the antennas employed in the cellular phone 1 can be easily powered and grounded.

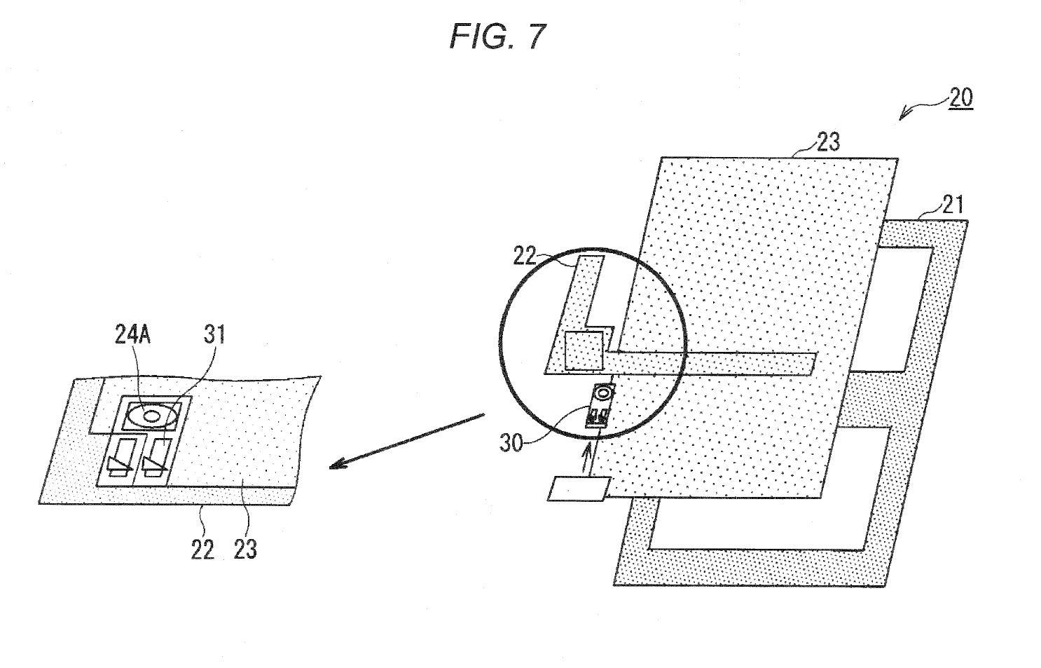

FIG. 7 is an exploded perspective view showing another example in which in the antenna integrally-formed frame 20 of the cellular phone 1, a coaxial connector 24A of the antenna board 22 is caused to be contacted to the sheet metal 23 by employing, for example, a plate spring 29. As shown in FIG. 7, while a sub-board 30 which is not integrally molded with the resin frame 21 is prepared, the plate spring 31 and the coaxial connector 24A are mounted on the sub-board 30 so as to power the antenna.

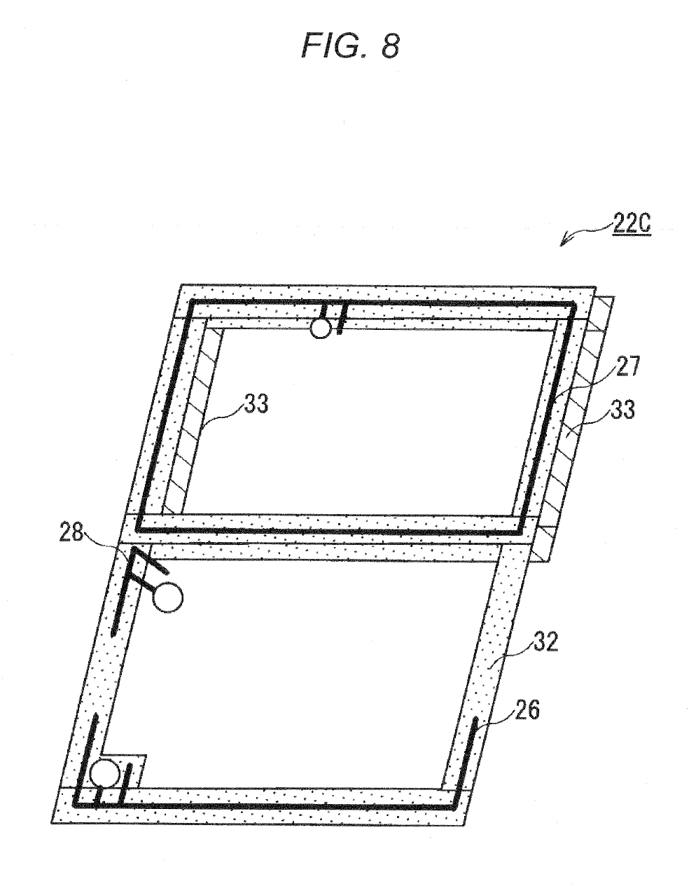

FIG. 8 is a diagram schematically showing an antenna integrally-formed frame 20C in which an antenna board 22C is made by a flexible printed board 32 in the cellular phone 1. As shown in FIG. 8, the antenna board 22C manufactured by integrally molding the flexible printed board 32 with a magnetic body 33 is molded with the resin frame 21. As the magnetic body 33, for example, ferrite which contains an iron oxide as a major component, and the like may be used. Because, characteristics of magnetic bodies made of a rubber series are deteriorated at temperatures between 60° C. and 70° C., whereas the characteristic of ferrite is not deteriorated up to several hundreds of centigrade degrees. Also, if a flexible printed board is employed, then there is a weak point that the flexible printed board 32 may be easily peeled. However, the weak point may be overcome by adhering the flexible printed board 32 by employing a catalyst, or the like.

As previously described, even if the antenna board 22C has the flexible characteristic, a similar effect may be realized. Also, in the cellular phone 1, since a strength maintaining member (sheet plate 23 etc.), a board, and furthermore, a magnetic body are molded with a resin in an integral manner, the above-described techniques may also be applied to antennas on which an RFID and the magnetic body are loaded.

Although such an example that the antenna board 22 where the antenna is mounted, and the sheet metal 23 are integrally molded with the resin frame 21 has been exemplified, the embodiment is not limited thereto. Alternatively, a board on which a plurality of components such as active parts (IC, LSI etc.) are mounted may be molded with the resin frame 21 in an integral manner.

Also, the antenna integrally-formed frames 20, 20A, 20C are built in the corresponding cellular phones 1 respectively under such a condition that the board of the display, the board of the keyboard, and the like are fixed on one plane of each of the frames 20, 20A, 20B, 20C, whereas the board of the CPU, the battery pack, and the like are fixed on the other plane thereof.

In the embodiment, although such an example that the antenna integrally-formed frames 20, 20A, 20B, 20C are built in the housing 10 respectively has been exemplified, the embodiment is not limited thereto. Alternatively, the cellular phone 1 may be manufactured without employing the housing 10 by the following method: That is, the display, the board of the keyboard, and the like may be fixed on one plane of each of the antenna integrally-formed frames 20, 20A, 20B, 20C by utilizing, for example, a double-faced adhesive tape, or the like; the board of the CPU, the battery pack, and the like may be fixed on the other plane thereof by employing, for instance, a double-faced adhesive tape, or the like; and the surfaces thereof may be decorated by decoration sheets, or the like.

Since a thickness of a housing is approximately 0.6 mm, assuming that both a front plane and a rear plane of the cellular phone are covered by the above-described housing, a thickness of approximately 1.2 mm is occupied only by the housing. As a consequence, since the antenna integrally-formed frames 20, 20A, 20B, 20C are employed, the utilization of the above-described housing 10 can be omitted, so that the cellular phone 1 can be made slim while the strengths with respect to the external force and the functional characteristics are maintained.

According to the mobile terminal (cellular phone 1) related to the embodiment, since the board and the sheet metal are molded with the frame resin in the integral manner, total number of the components and the mounting steps can be reduced, so that the fluctuations in the mounting positions can be suppressed.

Although the cellular phones 1 have been described as the inventive idea of the embodiment, the embodiment is not limited only thereto. Alternatively, the inventive idea may be applied to the electronic devices such as a Personal Handy-phone System (PHS), a Personal Digital Assistant (PDA), a so-called “net book” (network notebook type personal computer), a portable game machine, a portable television, and the like.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A mobile terminal comprising:
a board in which an electronic circuit is mounted;
a resin frame configured to hold the board; and
a sheet metal configured to maintain strength of the resin frame;
wherein the resin frame is configured to be integrally molded with the board and the sheet metal.

2. The terminal of claim 1, wherein the board is configured to include an antenna board formed by patterning an antenna.

3. The terminal of claim 2, wherein the antenna board is configured to include a coaxial connector for powering the antenna, and the antenna board is configured to be integrally molded with the resin frame so as to expose the coaxial connector.

4. The terminal of claim 2, wherein the antenna board is configured to include a coaxial connector for powering the antenna, and the antenna board is configured to be integrally molded with the resin frame to connect the coaxial connector via a plate spring to another board.

5. The terminal of claim 2, wherein the antenna board is configured to include a coaxial connector for powering the antenna, and the antenna board is configured to be integrally molded with the resin frame to connect the coaxial connector via a plate spring to the sheet plate.

6. The terminal of claim 2, wherein the antenna board is configured to have a shape which is coincident with a shape of a portion of the resin frame, and the antenna board is configured to be integrally molded with the resin frame in line with the portion of the resin frame.

7. The terminal of claim 2, wherein the antenna board is configured to have a shape which is coincident with a shape of the entire resin frame, and the antenna board is configured to be integrally molded with the resin frame in line with the shape of the resin frame.

8. The terminal of claim 1, wherein the sheet plate is formed to have an outer shape which is coincident with a shape of the resin frame, and the sheet plate is integrally molded with the resin frame to cover an entire plane of an inner portion of the resin frame.

9. The terminal of claim 1, wherein an active element is mounted on the board, and the board and the sheet metal are molded with the resin frame in the integral manner.

10. The terminal of claim 1, wherein the resin frame is formed in a shape having at least two opening portions.

11. The terminal of claim 9, wherein the resin frame includes a supporting rod for maintaining strengths of the resin frame with respect to external forces.

12. The terminal of claim 2, wherein a plurality of antennas are patterned on the antenna board.

13. The terminal of claim 2, wherein the antenna board is formed by molding the board, a magnetic body, and the sheet metal in the integral manner.

14. The terminal of claim 2, wherein the antenna board has flexibility.

15. The terminal of claim 14, wherein the antenna board includes a flexible printed board.

16. A method of manufacturing a mobile terminal, comprising:
fixing a board and a sheet metal respectively at given positions into a mold die;
flowing a resin into the metal die to form a resin frame;
integrally molding the board and the sheet metal with the resin frame; and
containing the molded resin frame into a housing of the mobile terminal.

17. The method of claim 16, wherein the board is configured to include an antenna board formed by patterning an antenna.
